(19) United States
(12) Patent Application Publication
(10) Pub. No.: US 2014/0285986 A1
(43) Pub. Date: Sep. 25, 2014

(54) ELECTRONIC DEVICE FOR VEHICLE

(71) Applicant: DENSO CORPORATION, Kariya-city (JP)

(72) Inventor: Yoshimasa Sano, Tokoname-city (JP)

(73) Assignee: DENSO CORPORATION, Kariya-city (JP)

(21) Appl. No.: 14/220,385

(22) Filed: Mar. 20, 2014

(30) Foreign Application Priority Data
Mar. 25, 2013 (JP) 2013-062691

(51) Int. Cl. H05K 9/00; H05K 7/02

(52) U.S. Cl. CPC H05K 9/0067; H05K 7/02
USPC 361/752

(57) ABSTRACT

An electronic device for a vehicle has a housing, a pair of metal rails, a circuit board, a fastening member, and a conductive member. The housing includes an attaching portion to be attached to an attaching part of the vehicle and provides an interior space therein. The circuit board has an electronic circuit. One of the pair of metal rails holds a first side of the circuit board, and the other of the pair of metal rails holds a second side of the circuit board. The fastening member is made of metal and fastens the attaching portion to the attaching part of the vehicle. The conductive member electrically connects the pair of metal rails to the fastening member or the attaching part of the vehicle. The circuit board has a conductive portion. The conductive portion electrically connects the electronic circuit to the pair of metal rails.

### CROSS REFERENCE TO RELATED APPLICATION

This application is based on Japanese Patent Application No. 2013-62691 filed on Mar. 25, 2013, the disclosure of which is incorporated herein by reference in its entirety.

### TECHNICAL FIELD

The present disclosure relates to an electronic device for a vehicle.

### BACKGROUND

Conventionally, when a circuit board is fixed in a vehicle, the circuit board is fixed to a vehicle-side attaching part after the circuit board is housed in an interior space of a housing, to protect elements mounted to the circuit board. As JP 2007-329003A (corresponding to US 2009/0251843 A1) discloses, it is well-known that the elements mounted on the circuit board and the housing are grounded by a fastening member such as screw.

However, when a device such as the electronic device for a vehicle described above is grounded by the fastening member, at least a part of the housing contacting the fastening member is required to be made of a conductive material such as metal. Therefore, the housing may become heavier in weight, and increasing of weight of the housing becomes disadvantageous for downsizing. Further, by using the fastening member, a number of components increases. In addition, since the fastening processes are required, an increase in a cost is caused due to an increase of a workload.

### SUMMARY

The present disclosure has been made in view of the foregoing points, and it is an objective of the present disclosure to provide an electronic device for a vehicle, which can be grounded without a fastening member for fixing a circuit board.

According to an example of the present disclosure, there is provided an electronic device including a housing, a pair of metal rails, a circuit board, a fastening member, and a conductive member. The housing includes an attaching portion to be attached to an attaching part of the vehicle and provides an interior space therein. One of the pair of metal rails is arranged at a first side of the interior space, and the other of the pair of metal rails is arranged at a second side of the interior space opposite to the first side of the interior space. The circuit board has an electronic circuit and is disposed in the interior space. The one of the pair of metal rails holds a first side of the circuit board, and the other of the pair of metal rails holds a second side of the circuit board opposite to the first side of the circuit board. The fastening member is made of metal. The fastening member fastens the attaching portion of the housing to the attaching part of the vehicle. The conductive member electrically connects the pair of metal rails to the fastening member or the attaching part of the vehicle. The circuit board has a conductive portion at the first side and the second side of the circuit board. The conductive portion electrically connects the electronic circuit to the pair of metal rails.

By employing such a configuration, the circuit board has the conductive member electrically connecting the electronic circuit and the pair of metal rails with each other when the pair of metal rails holds the both end parts of the circuit board. Therefore, the electronic circuit and the vehicle-side attaching part are electrically connected with each other by fastening the attaching portion of the housing to the vehicle-side attaching part using the fastening member after the pair of metal rails holds the circuit board. Thus, the electronic device for a vehicle is grounded without fastening the circuit board by a fastening member.

As described above, according to the present disclosure, the housing is made of resin, and the electronic device is grounded without fixing the circuit board by the fastening member. Therefore, the electronic device of the present disclosure can be lighter in weight, and can be low in cost by reducing a number of components and workloads.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a cross-sectional view illustrating an electronic device taken along a line I-I in FIG. 2, according to a first embodiment;

FIG. 2 is a plane view illustrating the electronic device according to the first embodiment;

FIG. 3 is an exploded perspective view illustrating the electronic device according to the first embodiment;

FIG. 4A is a cross-sectional view illustrating a circuit board of the electronic device;

FIG. 4B is an enlarged view illustrating a part IVB of FIG. 4A;

FIG. 5 is a cross-sectional view illustrating a resin case of the electronic device taken along a line V-V in FIG. 6, according to the first embodiment;

FIG. 6 is a cross-sectional view illustrating the resin case taken along a line VI-VI in FIG. 5, according to the first embodiment;

FIG. 7 is a cross-sectional view illustrating an electronic device according to a second embodiment;

FIG. 8 is a cross-sectional view illustrating an electronic device according to a third embodiment;

FIG. 9 is a cross-sectional view illustrating an electronic device according to a fourth embodiment;

FIG. 10 is an exploded perspective view illustrating the electronic device according to the fourth embodiment, in a state before the electronic device is assembled;

FIG. 11 is a cross-sectional view illustrating an electronic device according to a fifth embodiment;

FIG. 12 is an exploded perspective view illustrating the electronic device according to the fifth embodiment, in a state before the electronic device is assembled;

FIG. 13 is a cross-sectional view illustrating an electronic device according to a sixth embodiment; and

FIG. 14 is an exploded perspective view illustrating the electronic device according to the sixth embodiment, in a state before the electronic device is assembled.

### DETAILED DESCRIPTION

Embodiments of the present disclosure will be described hereafter referring to drawings. In the embodiments, a part that corresponds to a matter described in a preceding embodiment may be assigned with the same reference number, and redundant explanation for the part may be omitted. Drawings referred for description are views, and it should be noted that a shape or a dimension of each component shown in the drawings may not be always exact.

Embodiments of the present disclosure, which will be described hereinafter, are examples where an air bag electronic control unit (i.e., an air bag ECU) is used as an electronic device for a vehicle.

### First Embodiment

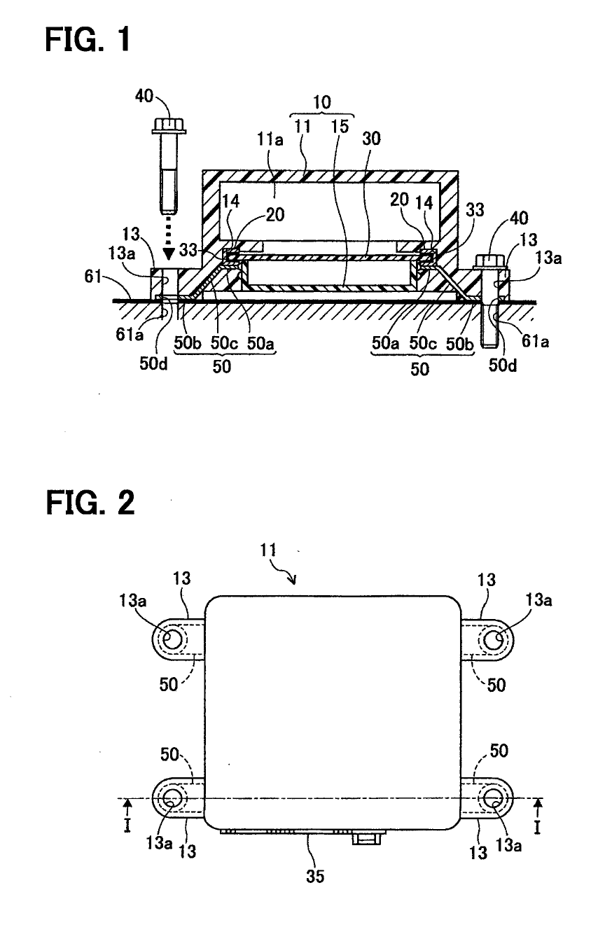

As shown in FIGS. 1-6, an electronic device for a vehicle according to the present embodiment has a housing 10 including a resin case 11 and a resin cover 15, a pair of metal rails 20, a circuit board 30, a fastening member 40, and a conductive member 50.

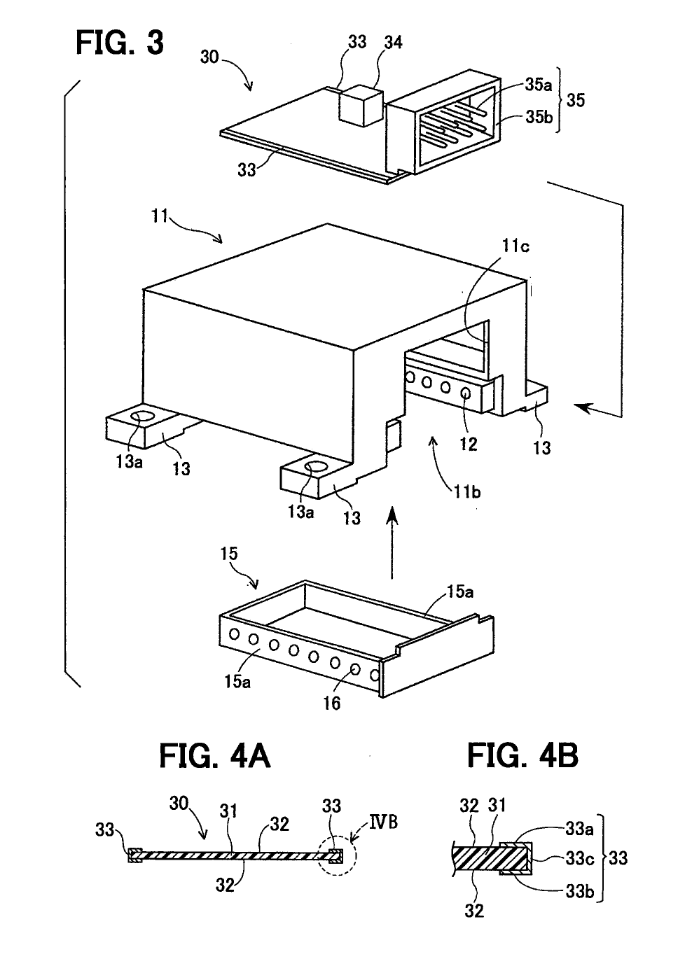

The resin case 11 is made of a plastic material to have a box shape. The resin case 11 provides an interior space 11 a therein and configures the housing 10. According to the present embodiment, polypropylene (PP) is used as the plastic material. As shown in FIG. 3, the resin case 11 includes a first opening 11b and a second opening 11c. The resin cover 15 is inserted to the first opening 11b to fit tightly to the first opening 11b. The circuit board 30 is inserted to the interior space 11 through the second opening 11c. The first opening 11b is provided at a bottom wall surface of the resin case 11 that is adjacent to a vehicle-side attaching part (i.e., a vehicle frame) 61. The resin case 11 includes sidewalls opposing to each other through the second opening 11c, and the inner surfaces of the sidewalls have recesses 12 to fix the resin cover 15, as shown in FIG. 3. The second opening 11c is provided to a sidewall, which connects the sidewalls having the recesses 12 with each other, as shown in FIG. 3.

As shown in FIGS. 2 and 3, an attaching portion 13 attaching and fastening the electronic device to the vehicle-side attaching part 61 is disposed to each peripheries of four corners of the bottom surface of the resin case 11. Therefore, four of the attaching portions 13 are disposed to the resin case 11 according to the first embodiment. A through hole 13a is provided to the attaching portion 13, and the fastening member 40 is inserted in the through hole 13a. Each of the inner surfaces of the sidewalls having the recesses 12 has a groove 14, and the two grooves 14 extend to be parallel with each other.

The resin cover 15 configuring the housing 10 is made of the same plastic material (e.g., PP) forming the resin case 11 by molding the plastic material to have a predetermined shape. The resin cover 15 has a box shape including a pair of sidewalls 15a opposing to each other, and the sidewalls 15a are tightly fitted to the first opening 11b of the resin case 11. The outer surface of the sidewall 15a has protruding portions 16. An entire top of the resin cover 15 is open. The resin cover 15 is designed to be generally the same size as the first opening 11b so as to be inserted to the first opening 11b of the resin case 11. Therefore, the protruding portions 16 protruding from the outer surfaces of the pair of sidewalls 15a contact an inner surface of the first opening 11b. According to the present embodiment, each of the protruding portions 16 has a dome shape, and each of the recesses 12 has a bowl shape to fit to the protruding portion 16.

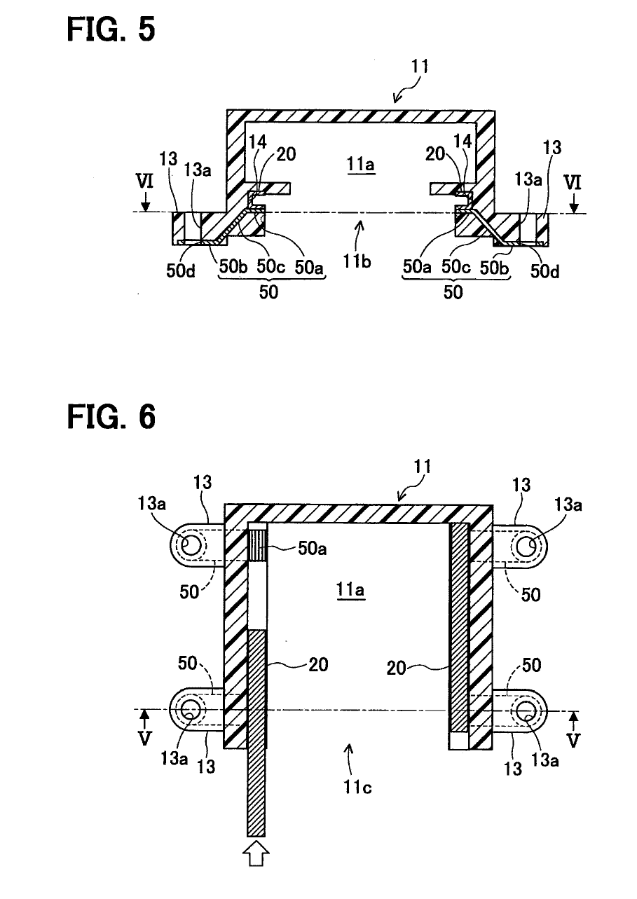

The pair of metal rails 20 is made of ferrous metal to have generally a U-shape in a cross section, and a length of the pair of metal rails 20 is shorter than a length of the groove 14. As shown in FIG. 5, each of the metal rails 20 is held by the groove 14 so that openings of the U-shape of the pair of metal rails 20 oppose to each other. As shown in FIG. 6, each of the pair of metal rails 20 is slid and inserted to the groove 14 via the second opening 11c.

As shown in FIG. 3 and FIG. 4A, the circuit board 30 has a board member 31, a conductive portion 33, an acceleration sensor 34, and a connector 35. The board member 31 includes an electronic circuit 32. The conductive portion 33 is arranged at a first end and a second end of the board member 31 opposing to each other. The acceleration sensor 34 is disposed to the board member 31. The connector 35 connects with an exterior apparatus. The board member 31 has a rectangular flat-plate shape, and the electronic circuit 32 is configured on both a top surface and a bottom surface of the board member 31. The board member 31 of the present embodiment is a printed circuit board. A printed wiring made of a specific metallic material and various electronic parts (not shown) configure the electronic circuit 32.

The conductive portion 33 is located at each of the first end and the second end of the board member 31 opposing to each other in a width direction of the board member 31. The width direction is a direction perpendicular to a thickness direction of the circuit board 30 and to a longitudinal direction of the pair of metal rails 20. As shown in FIG. 4B, the conductive portion 33 includes a first part 33a, a second part 33b, and a third part 33c. The first part 33a is configured on an end portion in the width direction on a top surface of the board member 31. The second part 33b is configured on an end portion in the width direction on a bottom surface of the board member 31. The third part 33c connects the first part and the second part with each other. The third part 33c is configured on a side surface of the board member 31 so that the first part 33a and the second part 33b are electrically connected with each other via the third part 33c. The first part 33a and the printed wiring on the top surface of the board member 31 are electrically connected with each other. The second part 33b and the printed wiring on the bottom surface of the board member 31 are connected with each other. That is, the conductive portion 33 is configured integrally with the printed wiring of the electronic circuit 32 by the same metallic material providing the printed wiring.

The acceleration sensor 34 is a G sensor detecting an acceleration of a vehicle. The acceleration sensor 34 is located on the electronic circuit 32 of the board member 31. The circuit board 30 of the present embodiment is for an air bag electronic control unit (i.e., an air bag ECU) detecting an acceleration of a vehicle and operating a deployment control of an air bag based on the detection result.

As shown in FIG. 3, the connector 35 includes connector pins 35a and a housing 35b made of an insulating material. The connector pins 35a are disposed to the housing 35b so that one end of the connector pin 35a is mounted to the board member 31 and that the other end of the connector pin 35a is exposed to outside the housing 10. For example, the connector pins 35a are coupled with, for example, a wiring in a vehicle such as a vehicle harness.

The circuit board 30 having such a configuration described above is inserted in the pair of metal rails 20 through the second opening 11c. Specifically, the first end of the circuit board 30 is slid and inserted to one of the pair of metal rails 20, and the second end of the circuit board 30 is slid and inserted to the other one of the pair of metal rails 20. Accordingly, the circuit board 30 is arranged in the interior space 11a in a state where the pair of metal rails 20 holds the first end and the second end of the circuit board 30. When the pair of metal rails 20 holds the first end and the second end of the circuit board 30, the electronic circuit 32 and the pair of metal rails 20 are electrically connected to each other via the conductive portion 33. The conductive portion 33 is disposed at both of the first end and the second end of the board member 31 opposite from each other in the width direction.

As shown in FIG. 1, the fastening member 40 fastens the attaching portion 13 of the housing 10 to the vehicle-side attaching part 61. The vehicle-side attaching part 61 of the present embodiment is disposed to a vehicle frame of a vehicle floor. The vehicle-side attaching part 61 has a through hole 61a to be positioned coinciding with the through hole 13a of the attaching portion 13. According to the present embodiment, an attaching bolt and a nut (not shown) made of metal are used as the fastening member 40, and the fastening member 40 is hereinafter referred to as the attaching bolt 40 as needed. However, the fastening member 40 is not limited to the bolt, and may be a screw or stud. A tip part of a shaft of the attaching bolt 40 is coupled to the nut to be fastened together, after the shaft of the attaching bolt 40 is inserted in the through hole 13a of the attaching portion 13 and the through hole 61a of the vehicle-side attaching part 61. Accordingly, the attaching portion 13 of the housing 10 is fastened to the vehicle-side attaching part 61.

The conductive member 50 electrically connects the pair of metal rails 20 to the fastening member 40 or the vehicle-side attaching part 61. The conductive member 50 of the present embodiment is made of a metal frame buried in the resin case 11 by insert molding when the resin case 11 is molded. The conductive member 50 is made of a ferrous metal plate curved to form an upper part 50a, a lower part 50b, and a middle part 50c. The middle part 50c is connected to each of the upper part 50a and the lower part 50b to be sloped with respect to the upper part 50a and the lower part 50b.

The conductive member 50 is buried to extend from the first opening 11b of the resin case 11 to the attaching portion 13. That is, as shown in FIG. 6, an upper surface of the upper part 50a is exposed in the groove 14 and contacts a bottom surface of the metal rail 20 disposed in the groove 14. Accordingly, the conductive member 50 and the metal rail 20 are electrically connected with each other. As shown in FIGS. 1 and 5, the lower part 50b has a through hole 50d corresponding to the through hole 13a of the attaching portion 13 in location. The attaching bolt 40 is inserted in the through hole 50d when the attaching bolt 40 is inserted in the through hole 13a. A bottom surface of the lower part 50b is exposed on a bottom surface of the attaching portion 13 and contacts the vehicle-side attaching part 61. Accordingly, the conductive member 50 and the vehicle-side attaching part 61 are electrically connected with each other.

Therefore, by disposing the conductive portion 33 to the first end and the second end of the circuit board 30 being held by the pair of metal rails 20, the electronic circuit 32 of the circuit board 30 is electrically connected with a part of a vehicle (e.g., the vehicle-side attaching part 61). The electronic circuit 32 is grounded via the conductive portion 33, the pair of metal rails 20, the conductive member 50, and the attaching bolt (i.e., the fastening member) 40.

As described above, in the electronic device for a vehicle according to the present embodiment, the circuit board 30 has the conductive portion 33. When the first end and the second end of the circuit board 30 are held by the pair of metal rails 20, the conductive portion 33 electrically connects the electronic circuit 32 and the pair of metal rails 20 with each other. The attaching portion 13 of the housing 10 is fastened to the vehicle-side attaching part 61 by the fastening member 40 after the pair of metal rails 20 hold the circuit board 30. Therefore, the vehicle-side attaching part 61 and elements mounted to the circuit board 30 are electrically connected with each other. Accordingly, grounding is secured without using a fastening member for directly fastening the circuit board 30. In addition, the housing 10 is made of the plastic material. Therefore, the electronic device of the present embodiment can be lighter in weight, and a cost can be lower by reducing a number of components and workloads.

Further, the conductive portion 33 is integrally made of the same metallic material configuring the wiring of the electronic circuit 32. Therefore, the conductive portion 33 can be easily formed with the electronic circuit 32 simply and easily when the board member 31 is manufactured.

Moreover, the conductive portion 33 includes the first part 33a, the second part 33b, and the third part 33c. The first part 33a is configured at the end portion along the top surface of the board member 31. The second part 33b is configured at the end portion along the bottom surface of the board member 31. The third part 33c connects the first part 33a and the second part 33b with each other. The third part 33c is provided along a side surface of the board member 31 and connected with both of the first part 33a and the second part 33b so that the first part 33a and the second part 33b are electrically connected with each other via the third part 33c. Accordingly, each of the pair of metal rails 20 can be electrically connected with the electronic circuit 32 of the board member 31 certainly.

### Second Embodiment

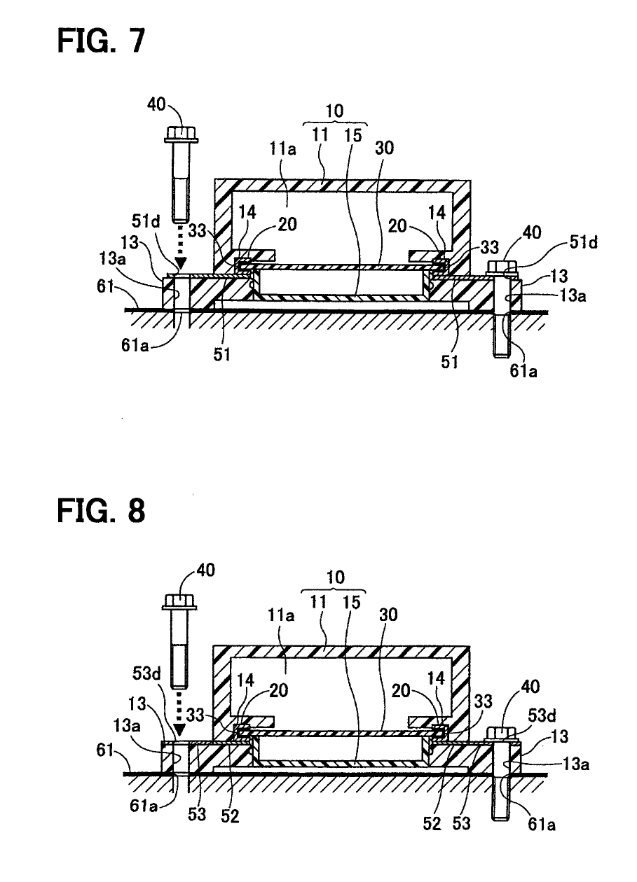

An electronic device for a vehicle according to a second embodiment will be described referring to FIG. 7. A basic structure of the electronic device is generally the same as that of the first embodiment. A structure of a conductive member of the present embodiment is different from a structure of the conductive member 50 of the first embodiment. Therefore, description about components and structures common with that of the first embodiment will be omitted, and changed points changed from the first embodiment and considerable points will be described.

The conductive member of the second embodiment is made of a metal frame 51. The metal frame 51 is configured integrally with the metal rail 20 disposed in the groove 14. The metal frame 51 is made of the same ferrous metallic material as the metal rail 20 to have a rectangular flat-plate shape without curved part. A first end portion of the metal frame 51 in a longitudinal direction of the metal frame 51 is buried in the resin case 11. The first end portion of the metal frame 51 connects with the metal rail 20. A second end portion of the metal frame 51 in the longitudinal direction extends from the resin case 11 along the attaching portion 13. An upper surface of the second end portion of the metal frame 51 is exposed outside. A through hole 51 d is provided at the second end portion of the metal frame 51 to correspond to the through hole 13a of the attaching portion 13 in location, and the attaching bolt 40 is inserted to both the through hole 13a and the through hole 51d.

Similar to the first embodiment, the circuit board 30 of the second embodiment has the conductive portion 33. The conductive portion 33 electrically connects with the electronic circuit 32 and the pair of metal rails 20, when the pair of metal rails 20 holds the first end and the second end of the circuit board 30.

According to the electronic device of the second embodiment described above, similar to the first embodiment, the attaching portion 13 of the resin case 11 is fastened to the vehicle-side attaching part 61 by the attaching bolt (i.e., the fastening member) 40 and a nut (not shown). In this case, a head of the attaching bolt 40 inserted in the through hole 13a of the attaching portion 13 contacts a periphery of the second end portion of the metal frame 51 on the upper surface of the attaching portion 13. Further, the vehicle-side attaching part 61 contacts the nut coupled to the tip of the attaching bolt 40 protruding from the through hole 61a of the vehicle-side attaching part 61. Accordingly, the metal frame 51 is electrically connected with the vehicle-side attaching part 61 via the attaching bolt 40 and the nut.

Similar to the first embodiment, the conductive portion 33 is disposed at both of the first end and the second end of the circuit board 30 held by the pair of metal rails 20 in the second embodiment. Therefore, the electronic circuit 32 provided to the circuit board 30 is electrically connected with a part of a vehicle (e.g., the vehicle-side attaching part 61) via the conductive portion 33, the pair of metal rails 20, the metal frame (i.e., the conductive member) 51, and the attaching bolt (i.e., the fastening member) 40. Accordingly, the electronic circuit 32 is grounded via the vehicle.

Thus, the electronic circuit 32 and the pair of metal rails 20 are electrically connected via the conductive portion 33 when the pair of metal rails 20 hold the first end and the second end of the circuit board 30. Therefore, the present embodiment can have the same effects as the first embodiment, for example, securing grounding without fastening the circuit board 30 directly by a fastening member. Specifically, in the second embodiment, the metal frame 51 as the conductive member is configured integrally with the pair of metal rails 20. Therefore, a number of components can be further reduced.

### Third Embodiment

An electronic device for a vehicle according to a third embodiment will be described referring to FIG. 8. A basic structure of the electronic device is generally the same as that of the first embodiment. A structure of a conductive member of the third embodiment is different from a structure of the conductive member 50 of the first embodiment. Therefore, description about components and structures common with that of the first embodiment will be omitted, and changed points changed from the first embodiment and considerable points will be described.

The conductive member of the third embodiment is configured by a metal frame 52 and a conductive element 53. The metal frame 52 is configured integrally with the metal rail 20 and buried in the resin case 11. The conductive element 53 is made of a conductive material coating a surface of the resin case 11 to be electrically connected with the metal frame 52. The structure of the conductive member of the third embodiment is different from that of the second embodiment. Specifically, with respect to the second embodiment, in which the metal frame (i.e., the conductive member) 51 is configured integrally with the metal rail 20, the conductive member of the third embodiment is configured by the metal frame 52 and the conductive element 53.

The metal frame 52 is integrally made of the same metallic material as the metal rail 20, and an entire of the metal frame 52 is buried in the resin case 11 (i.e., the housing 10). That is, the metal frame 52 is equivalent to the first end portion of the metal frame 51 of the second embodiment buried in the resin case 11.

The conductive element 53 is made of a conductive material coated on the upper surface of the attaching portion 13 (i.e., the housing 10) by plating such as zinc plating. The conductive element 53 electrically connects with the metal frame 52. That is, the conductive element 53 is equivalent to the second end portion of the metal frame 51 of the second embodiment. An end periphery of the conductive element 53 has a through hole 53d provided to coincide with the through hole 13a of the attaching portion 13 in location. The attaching bolt 40 is inserted to both of the through hole 13a and the through hole 53d.

Similar to the first embodiment, the circuit board 30 of the third embodiment has the conductive portion 33. The conductive portion 33 electrically connects with the electronic circuit 32 and the pair of metal rail 20 when the pair of metal rails 20 holds the first end and the second end of the circuit board 30.

According to the electronic device of the third embodiment, similar to the first embodiment, the attaching portion 13 of the resin case 11 is fastened to the vehicle-side attaching part 61 by the attaching bolt (i.e., the fastening member) 40 and the nut (not shown). Accordingly, the electronic circuit 32 of the circuit board 30 is electrically connected to a part of a vehicle (e.g., the vehicle-side attaching part 61) via the conductive portion 33, the pair of metal rails 20, the metal frame (i.e., the conductive member) 52, the conductive element 53, the attaching bolt 40, and the nut. Therefore, the electronic circuit 32 is grounded via the vehicle.

Therefore, according to the electronic device for a vehicle of the third embodiment, the electronic circuit 32 and the pair of metal rails 20 are electrically connected via the conductive portion 33 when the pair of metal rails 20 holds the first end and the second end of the circuit board 30. Therefore, the present embodiment can have the same effects as the first embodiment, for example, securing grounding without fastening the circuit board 30 directly by a fastening member.

Specifically, although the metal frame 52 of the second embodiment is exposed on the upper surface of the attaching portion 13, the entire of the metal frame 52 is buried in the resin case 11 without being exposed. Therefore, the metal frame 52 is restricted from being displaced and causing an abnormality when the resin case 11 is molded. Accordingly, the resin case 11 can be molded easily.

### Fourth Embodiment

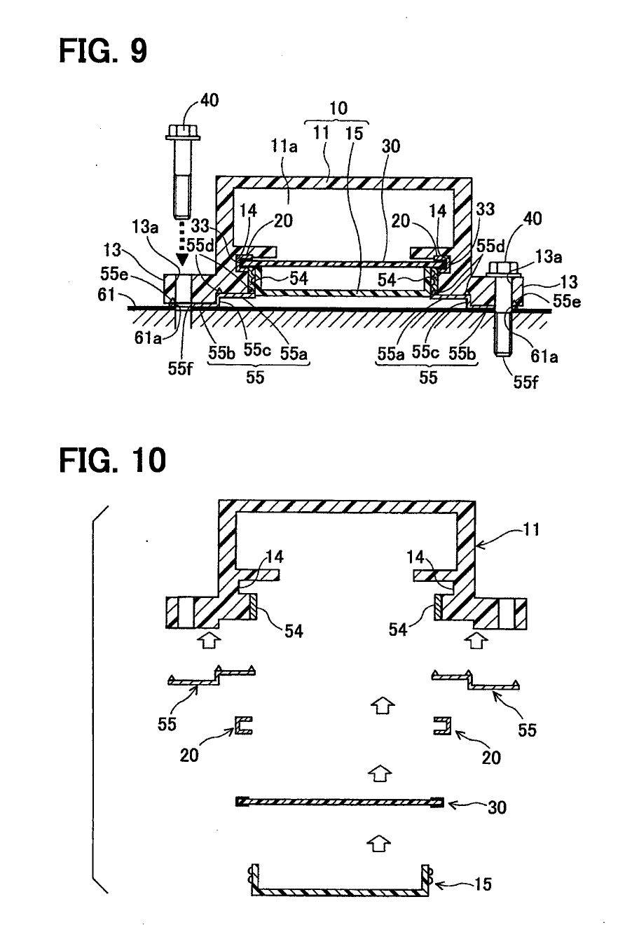

An electronic device for a vehicle according to a fourth embodiment will be described referring to FIGS. 9 and 10. A basic structure of the electronic device is generally the same as that of the first embodiment. A structure of a conductive member of the fourth embodiment is different from a structure of the conductive member 50 of the first embodiment. Therefore, description about components and structures common with that of the first embodiment will be omitted, and changed points changed from the first embodiment and considerable points will be described.

As shown in FIG. 9, the conductive member of the fourth embodiment is configured by a conductive element 54 and a metal frame 55. The conductive element 54 is made of a conductive material coated on a surface of the resin case 11 (i.e., the housing 10) to electrically connect with the metal rail 20. The metal frame 55 is supported by the resin case 11 (i.e., the housing 10) so that one end of the metal frame 55 contacts the conductive element 54 and that the other end of the metal frame 55 contacts the vehicle-side attaching part 61.

The conductive element 54 is provided on a pair of inner surface of the first opening 11b of the resin case 11 opposing to each other, by plating similar to the third embodiment. The conductive element 54 is provided at a location corresponding to four of the attaching portions 13. The conductive element 54 is provided to extend from an opening edge of the first opening 11 b to the groove 14. The conductive element 54 contacts the metal rail 20 disposed in the groove 14 at an end part of the conductive element 54 adjacent to the groove 14. The conductive element 54 is electrically connected with the metal rail 20. Similar to the first embodiment, each of the inner surfaces of the first opening 11b has the recesses 12. The recess 12 and the protruding portion 16 disposed to the resin cover 15 are fitted tightly with each other.

The metal frame 55 is made of a rectangular metal plate curved to have a crank shape in cross section and to provide an upper part 55a, a lower part 55b, and a middle part 55c. The middle part 55c is arranged to be connected with both the upper part 55a and the lower part 55b. An upper surface of the upper part 55a has a wedge-shaped portion 55d at both ends of the upper part 55a in a longitudinal direction of the metal frame 55. The wedge-shaped portion 55d protrudes from the upper surface of the upper part 55a. An upper surface of the lower part 55b has a wedge-shaped portion 55e at an end of the lower part 55b that is opposite to the middle part 55c. The wedge-shaped portion 55e protrudes from the upper surface of the lower part 55b. The wedge-shaped portion 55d and the wedge-shaped portion 55e are made of the same material forming the metal frame 55. The lower part 55b has a through hole 55f to coincide with the through hole 13a in location, and the attaching bolt 40 is inserted to both of the through hole 13a and the through hole 55f.

The metal frame 55 is attached to the resin case 11 so that the upper surface of the upper part 55a opposes to a bottom wall surface of the resin case 11 and that the bottom wall surface of the lower part 55b opposes to the vehicle-side attaching part 61. In this case, the upper surface of the lower part 55b opposes to a surface of the attaching portion 13, and the surface of the attaching portion 13 opposes to the vehicle-side attaching part 61. An end part of the upper part 55a opposite to the middle part 55c contacts the conductive element 54. The metal frame 55 and the conductive element 54 are electrically connected with each other. The metal frame 55 is fixed to the resin case 11 by the wedge-shaped portion 55d and the wedge-shaped portion 55e fitting into the resin case 11.

As shown in FIG. 10, when the electronic device of the fourth embodiment is constructed, the metal rail 20, the circuit board 30, and the resin cover 15 are attached to the resin case 11 in this order after the metal frame 55 is attached to the resin case 11.

According to the electronic device of the fourth embodiment described above, similar to the first embodiment, the attaching portion 13 of the resin case 11 is fastened to the vehicle-side attaching part 61 by the attaching bolt (i.e., the fastening member) 40 and the nut (not shown). In this case, the bottom surface of the lower part 55b of the metal frame 55 contacts the vehicle-side attaching part 61, such that the metal frame 55 and the vehicle-side attaching part 61 are electrically connected with each other.

Further, each of the first end and the second end of the circuit board 30 held by the pair of metal rails 20 has the conductive portion 33. Accordingly, the electronic circuit 32 is electrically connected to a part of a vehicle (e.g., the vehicle-side attaching part 61) via the conductive portion 33, the pair of metal rails 20, the conductive element (i.e., the conductive member) 54, and the metal frame (i.e., the conductive member) 55. Therefore, the electronic circuit 32 is grounded via the vehicle.

The circuit board 30 has the conductive portion 33. When the pair of metal rails 20 supports the first end and the second end of the circuit board 30, the electronic circuit 32 and the pair of metal rails 20 are electrically connected with each other via the conductive portion 33 without a fastening member that directly fastens the circuit board 30. Therefore, the fourth embodiment can have the same effects, for example, securing grounding without a fastening member to directly fasten the circuit board 30, as the first embodiment.

Specifically, although the metal frame 52 of the third embodiment is buried in the resin case 11, according to the fourth embodiment, the metal frame 55 is fixed to the resin case 11 through the wedge-shaped portion 55d and the wedge-shaped portion 55e. Therefore, the resin case 11 can be formed easily. Moreover, an attaching location of the metal frame 55 is not required to be strict, so the metal frame 55 can be attached easily to the resin case 11.

### Fifth Embodiment

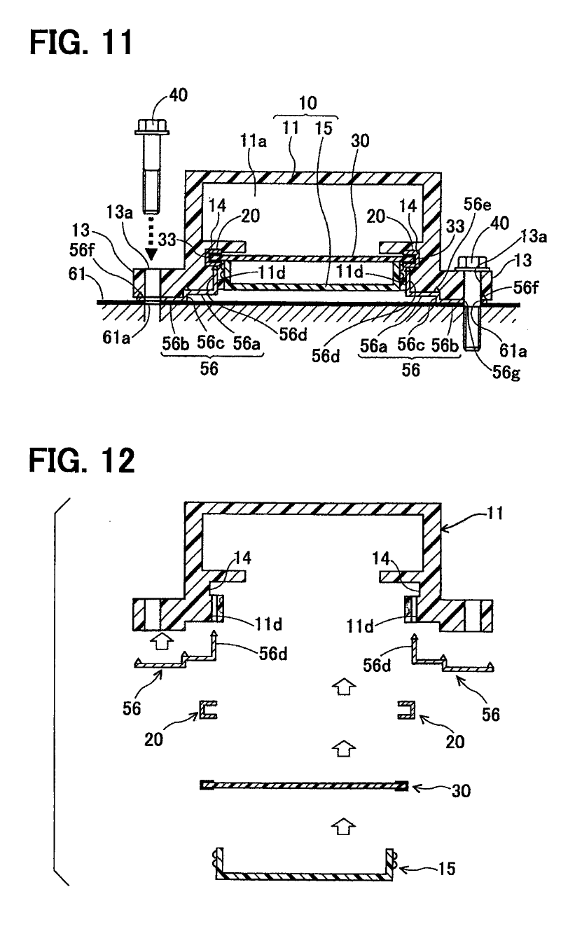

An electronic device for a vehicle according to a fifth embodiment will be described referring to FIGS. 11 and 12. A basic structure of the electronic device is generally the same as that of the first embodiment. A structure of a conductive member of the fifth embodiment is different from a structure of the conductive member 50 of the first embodiment. Therefore, description about components and structures common with that of the first embodiment will be omitted, and changed points changed from the first embodiment and considerable points will be described.

As shown in FIGS. 11 and 12, a resin case 11 of the fifth embodiment has a through hole 11d passing through the resin case 11, in other words, extending from a bottom wall surface of the resin case 11 to the groove 14. The through hole 11d is provided to a bottom wall of the resin case 11 defining the first opening 11b. Specifically, the through hole 11d is provided on a side of the resin case 11 that is opposite to the attaching portion 13 and passes through the resin case 11 in a thickness direction of the bottom wall of the resin case 11. Four of the through holes 11d are provided to the resin case 11 to correspond to the four attaching portions 13.

The conductive member 50 of the fifth embodiment is configured by a metal frame 56 including an insertion part 56d. The insertion part 56d is inserted in the housing 10 so that a tip part of the insertion part 56d contacts the metal rail 20. The metal frame 56 is made of a rectangular metal plate curved to have a crank shape in cross section to provide an upper part 56a, a lower part 56b, and a middle part 56c. The middle part 56c connects with both the upper part 56a and the lower part 56b.

The insertion part 56d is disposed to one end part of an upper surface of the upper part 56a opposite to the middle part 56c in a longitudinal direction of the upper part 56a. The insertion part 56d extends from the upper surface of the upper part 56a. The other end part of the upper surface of the upper part 56a adjacent to the middle part 56c has a wedge-shaped portion 56e protruding from the upper surface of the upper part 56a. Moreover, an end part of an upper surface of the lower part 56b opposite to the middle part 56c has a wedge-shaped portion 56f protruding from the upper surface of the lower part 56b. The insertion part 56d, the wedge-shaped portion 56e, and the wedge-shaped portion 56f are made of the same conductive material forming the metal frame 56. The lower part 56b has a through hole 56g corresponding to the through hole 13a of the attaching portion 13 in location, and the attaching bolt 40 is inserted to both of the through hole 13a and the through hole 56g.

The metal frame 56 of the fifth embodiment has the insertion part 56d instead of the wedge-shaped portion 55d of the metal, frame 55 of the fourth embodiment. The insertion part 56d is located at the one end part of the upper surface of the upper part 56a opposite to the middle part 56c. Another point of the fifth embodiment different from the fourth embodiment is a length of the upper. part 56a in the longitudinal direction. The length of the upper part 56a in the longitudinal direction is shorter than a length of the upper part 55a because the insertion part 56d is inserted to the through hole 11d of the resin case 11.

The metal frame 56 is attached to the resin case 11 so that the upper surface of the upper part 56a opposes to a bottom wall surface of the resin case 11 opposing to the vehicle-side attaching part 61. In this case, the upper surface of the lower part 55b opposes to a surface of the attaching portion 13 opposing to the vehicle-side attaching part 61. The insertion part 56d of the metal frame 56 is inserted to the through hole 11d of the resin case 11 so that the tip part of the insertion part 56d contacts the metal rail 20 disposed in the groove 14. Therefore, the metal frame 56 and the metal rail 20 are electrically connected with each other. The metal frame 56 is fixed to the resin case 11 by the wedge-shaped portion 56e and the wedge-shaped portion 56f fitting into the resin case 11.

As shown in FIG. 12, when the electronic device of the fifth embodiment is constructed, the metal rail 20, the circuit board 30, and the resin cover 15 are attached to the resin case 11 in this order after the metal frame 56 is attached to the resin case 11.

According to the electronic device of the fifth embodiment described above, similar to the first embodiment, the attaching portion 13 of the resin case 11 is fastened to the vehicle-side attaching part 61 by the attaching bolt (i.e., the fastening member) 40 and the nut (not shown). In this case, a bottom surface of the lower part 56b of the metal frame 56 contacts the vehicle-side attaching part 61. Therefore, the metal frame 56 electrically connects with the vehicle-side attaching part 61.

The circuit board 30 of the fifth embodiment has the conductive portion 33. When the pair of metal rails 20 supports the first end and the second end of the circuit board 30, the electronic circuit 32 and the pair of metal rails 20 are electrically connected with each other via the conductive portion 33 without a fastening member for directly fastening the circuit board 30. Therefore, the fifth embodiment can have the same effects as the first embodiment.

Specifically, according to the fifth embodiment, the metal frame 56 is used as the conductive member. The metal frame 56 has the insertion part 56d inserted in the through hole lid of the resin case 11 (i.e., the housing 10) so that the tip part of the insertion part 56d contacts the metal frame 20. Therefore, the metal frame 56 is attached to an appropriate location of the resin case 11 accurately and easily. Moreover, the resin case 11 is formed easily.

### Sixth Embodiment

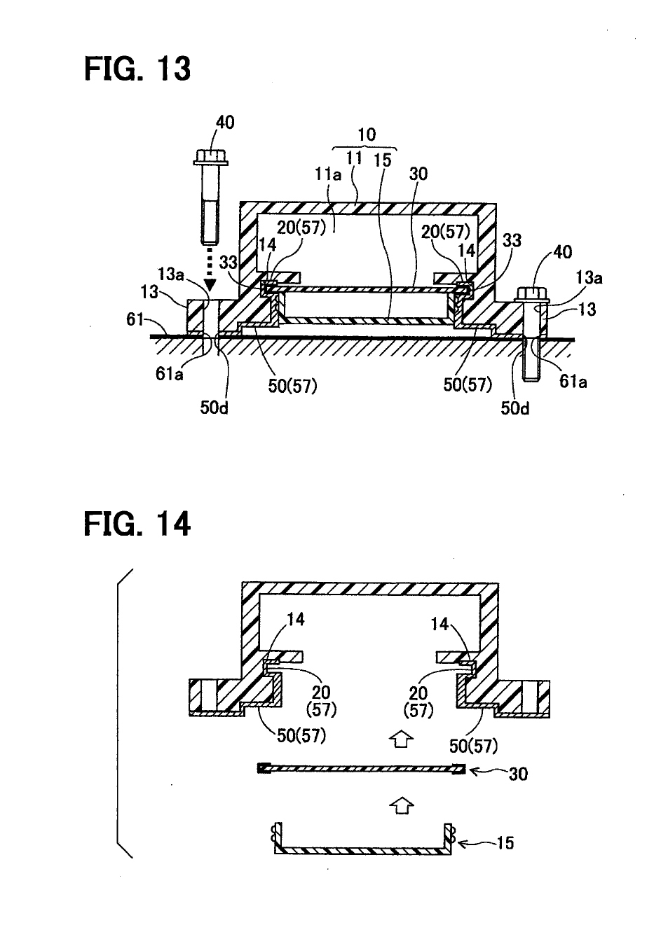

An electronic device for a vehicle according to a sixth embodiment will be described referring to FIGS. 13 and 14. A basic structure of the electronic device is generally the same as that of the first embodiment. Structures of a metal rail 20 and a conductive member 50 of the sixth embodiment are different from structures of the metal rail 20 the conductive member 50 of the first embodiment. Therefore, description about components and structures common with that of the first embodiment will be omitted, and changed points changed from the first embodiment and considerable points will be described.

As shown in FIG. 13, the metal rail 20 and the conductive member 50 of the sixth embodiment are configured integrally as a conductive element 57. The conductive element 57 is made of a conductive material coating a surface of the housing 10. That is, similar to the third embodiment, the conductive element 57 of the sixth embodiment is made of a conductive material plated on a surface of the groove 14 of the resin case 11, so as to provide the metal rail 20.

The metal frame 55 is attached to the bottom wall surface of the resin case 11 as the conductive member 50 in the fourth embodiment. In contrast, according to the sixth embodiment, the same plating as the third embodiment is applied to a bottom wall surface of the resin case 11. Thus, the conductive member 50 of the sixth embodiment is seamlessly integrated with the metal rail 20 as the conductive element 57. Accordingly, the metal rail 20 and the conductive member 50 are electrically connected with each other. The conductive member 50 of the sixth embodiment has a through hole 50d corresponding to the through hole 13a in location, and the attaching bolt 40 is inserted to both of the through hole 50d and the through hole 13a.

Similar to the first embodiment, the circuit board 30 of the sixth embodiment has the conductive portion 33 electrically connecting with both the electronic circuit 32 and each of the pair of the metal rails 20.

As shown in FIG. 14, when the electronic device of the sixth embodiment is configured, the resin cover 15 is attached to the resin case 11 to fit with each other after the circuit board 30 is slid and inserted to the pair of metal rails 20.

According to the electronic device of the sixth embodiment described above, similar to the first embodiment, the attaching portion 13 of the resin case 11 is fastened to the vehicle-side attaching part 61 by the attaching bolt (i.e., the fastening member) 40 and the nut (not shown). In this case, a bottom surface of the conductive element 57 as the conductive member 50 contacts the vehicle-side attaching part 61, and the conductive. element 57 and the vehicle-side attaching part 61 are electrically connected with each other.

Accordingly, the pair of metal rails 20 support the first end and the second end of the circuit board 30, and the conductive portion 33 is disposed to the first end and the second end of the circuit board 30. Therefore, the electronic circuit 32 provided on the circuit board 30 is electrically connected with a part of a vehicle (e.g., the vehicle-side attaching part 61), via the conductive portion 33, the pair of metal rails 20 (i.e., the conductive element 57), and the conductive member 50 (i.e., the conductive element 57). Thus, the electronic circuit 32 is grounded.

Moreover, the circuit board 30 of the sixth embodiment has the conductive portion 33. The electronic circuit 32 and the pair of metal rails 20 are electrically connected with each other via the conductive portion 33 without a fastening member for fastening directly the circuit board 30 when the pair of metal rails 20 supports the first end and the second end of the circuit board 30. Therefore, the sixth embodiment can have the same effects, for example, securing grounding without a fastening member for fastening the circuit board 30, as the first embodiment.

Specifically, in the sixth embodiment, the metal rail 20 and the conductive member 50 are configured integrally with each other as the conductive element 57 made of a conductive material coating the surface of the housing 10. Therefore, with respect to the first to fifth embodiments, the pair of metal rails 20 and the conductive member 50 are configured more easily.

### (Other Modification)

It should be noted that the present disclosure is not limited to the above embodiments. When only a part of a configuration is described in an embodiment, another preceding embodiment may be applied to the other parts of the configuration. The parts may be combined even if it is not explicitly described that the parts can be combined. The above embodiments may be partially combined even if it is not explicitly described that the embodiments can be combined, as long as there is no harm in the combination.

For example, PP is used as the plastic material forming the resin case 11 and the resin cover 15 of the housing 10. However, other plastic materials such as polybutylene terephthalate (PBT), polyethylene terephthalate (PET), polycarbonate (PC), ABS resin, or a polymer alloy of those resin materials can be used. The plastic material may have conductivity and may include a filler such as a grass fiber and a carbon fiber. A material forming the resin case 11 may be different from a material forming the resin cover 15.

Although grounding is secured at four locations having the attaching portion 13 of the resin case 11 according to the above embodiments, at least one location may be required to secure grounding.

Further, a sensor mounted in the electronic device is not limited to an acceleration sensor. The sensor may be a yaw rate sensor, a roll sensor, a gyroscope, or the like detecting a vehicle behavior.

What is claimed is:

1. An electronic device for a vehicle, comprising:
a housing including an attaching portion to be attached to an attaching part of the vehicle, the housing providing an interior space therein;
a pair of metal rails, wherein one of the pair of metal rails is arranged at a first side of the interior space, and the other of the pair of metal rails is arranged at a second side of the interior space opposite to the first side of the interior space;
a circuit board having an electronic circuit and disposed in the interior space, wherein the one of the pair of metal rails holds a first side of the circuit board, and the other of the pair of metal rails holds a second side of the circuit board opposite to the first side of the circuit board;
a fastening member made of metal, the fastening member fastening the attaching portion of the housing to the attaching part of the vehicle; and
a conductive member electrically connecting the pair of metal rails to the fastening member or the attaching part of the vehicle, wherein
the circuit board has a conductive portion at the first side and the second side of the circuit board, and
the conductive portion electrically connects the electronic circuit to the pair of metal rails.

2. The electronic device for a vehicle according to claim 1, wherein
the conductive portion is made of the same metallic material as a wiring of the electronic circuit, and
the conductive portion is configured integrally with the wiring of the electronic circuit.

3. The electronic device for a vehicle according to claim 1, wherein
the conductive portion includes:
a first part arranged at an end portion of an upper surface of the circuit board;
a second part arranged at an end portion of a lower surface of the circuit board; and
a third part arranged on a side surface of the circuit board and connecting the first part and the second part to each other.

4. The electronic device for a vehicle according to claim 1, wherein
the first side and the second side of the circuit board are slidable on the pair of metal rails.

5. The electronic device for a vehicle according to claim 1, wherein
the conductive member comprises a metal frame, and the metal frame is configured integrally with the pair of metal rails.

6. The electronic device for a vehicle according to claim 1, wherein
the conductive member includes:
a metal frame configured integrally with the pair of metal rails and buried in the housing; and
a conductive element covering a surface of the housing and connected to the metal frame.

7. The electronic device for a vehicle according to claim 1, wherein
the conductive member includes:
a conductive element covering a surface of the housing and connected to the pair of metal rails; and
a metal frame supported by the housing, wherein one end of the metal frame is in contact with the conductive element, and the other end of the metal frame is in contact with the fastening member or the attaching part of the vehicle.

8. The electronic device for a vehicle according to claim 1, wherein
the conductive member comprises a metal frame including an insertion part inserted in the housing, and
a tip part of the insertion part is in contact with the pair of metal rails.

9. The electronic device for a vehicle according to claim 1, wherein
the pair of metal rails and the conductive member are integrally configured by a conducive element covering a surface of the housing.
